(19) United States
(12) Patent Application Publication
(10) Pub. No.: US 2019/0057884 A1
(43) Pub. Date: Feb. 21, 2019

(54) CLEANING LIQUID SUPPLY UNIT, SUBSTRATE TREATING APPARATUS INCLUDING THE SAME, AND SUBSTRATE TREATING METHOD

(71) Applicant: SEMES CO., LTD., Chungcheongnam-do (KR)

(72) Inventors: MINHEE CHO, Chungcheongnam-do (KR); JAEHYEOK YU, Chungcheongnam-do (KR); SEHOON OH, Chungcheongnam-do (KR); TAE-KEUN KIM, Gyeonggi-do (KR); YERIM YEON, Hwaseong-si (KR); HAE RIM OH, Gyeongsangnam-do (KR); JI SOO JEONG, Seoul (KR)

(21) Appl. No.: 16/102,812

(22) Filed: Aug. 14, 2018

(30) Foreign Application Priority Data
Aug. 16, 2017 (KR) 10-2017-0103334

(51) Int. Cl. H01L 21/67; H01L 21/02

(52) U.S. Cl. CPC H01L 21/67051; B08B 3/024; H01L 21/02052

(57) ABSTRACT

Disclosed are relate to an apparatus for supplying a cleaning liquid to a substrate. The cleaning liquid supply unit includes a mixing container having a liquid mixing space in the interior thereof, a first supply member configured to supply a first liquid into the liquid mixing space, a second supply member configured to supply a second liquid that is different from the first liquid into the liquid mixing space, and a mixing member configured to mix the first liquid and the second liquid supplied into the liquid mixing space, and the mixing member may include a circulation line, through which the liquids in the liquid mixing space circulate, and a pressure adjusting member configured to provide a pressure to the liquids such that the liquids in the liquid mixing space flows into the circulation line and adjust the pressure.

### CROSS-REFERENCE TO RELATED APPLICATIONS

This application claims priority under 35 U.S.C. § 119 to Korean Patent Application No. 10-2017-0103334 filed on Aug. 16, 2017, in the Korean Intellectual Property Office, the disclosures of which are incorporated by reference herein in their entireties.

### BACKGROUND

Embodiments of the inventive concept described herein relate to an apparatus for supplying a cleaning liquid to a substrate.

Contaminants such as particles, organic contaminants, and metallic contaminants on a surface of a substrate greatly influence the characteristics and yield rate of a semiconductor device. Due to this, a cleaning process of removing various contaminants attached to a surface of a substrate is very important, and a process of cleaning a substrate is performed before and after unit processes for manufacturing a semiconductor. In general, a process of cleaning a substrate includes a cleaning liquid treating process of removing metallic substances, organic substances, and particles residing on a substrate by using a treatment liquid such as a cleaning liquid, a rinsing process of removing the cleaning liquid residing on the substrate by using pure water, and a drying process of drying the substrate by using an organic solvent, a supercritical fluid, or a nitrogen gas.

When the cleaning liquid is manufactured by mixing the surfactant chemical and the pure water, particles are formed in the cleaning liquid. The generated particles make it easy to remove particles when the substrate is cleaned.

FIG. 1 is a view schematically illustrating a general cleaning liquid supply unit 30. Referring to FIG. 1, the cleaning liquid supply unit 30 manufactures a cleaning liquid used for the above-mentioned cleaning liquid treating process and supplies the cleaning liquid to a substrate. The cleaning liquid supply unit 30 mixes a surfactant chemical containing surfactant and pure water to manufacture the cleaning liquid. In general, the cleaning liquid supply unit 30 supplies the surfactant chemical and pure water to a container 31, and mixes the surfactant chemical and the cleaning liquid by circulating the surfactant chemical and the pure water 32 in the container 31 through a circulation line 33. The mixed cleaning liquid is supplied to the substrate through a nozzle 34.

Generally, a pump 35 that provides a pressure to circulate the surfactant chemical and the pure water into the circulation line 33 is a bellows type pump, by which it is difficult to adjust pressure and maintain a uniform pressure, and a configuration for measuring a pressure in the circulation line is not provided. Accordingly, the pressure in the circulation line 33 cannot be adjusted.

Further, when the footprint of the apparatus is considered, the length of the circulation line 33 is restricted.

### SUMMARY

Embodiments of the inventive concept provide an apparatus and a method for adjusting a pressure in a circulation line.

Embodiments of the inventive concept also provide an apparatus and a method for extending the length of a circulation line within a limited distance.

Embodiments of the inventive concept also provide an apparatus and a method for increasing the sizes of particles in a cleaning liquid.

The problems that are to be solved by the inventive concept are not limited to the above-mentioned problems, and the unmentioned problems will be clearly understood by those skilled in the art to which the inventive concept pertains from the specification and the accompanying drawings.

The invention concept provides a cleaning liquid supply unit for supplying a cleaning liquid that cleans a substrate. The cleaning liquid supply unit including a mixing container having a liquid mixing space in the interior thereof, a first supply member configured to supply a first liquid into the liquid mixing space, a second supply member configured to supply a second liquid that is different from the first liquid into the liquid mixing space, and a mixing member configured to mix the first liquid and the second liquid supplied into the liquid mixing space, and the mixing member may include a circulation line, through which the liquids in the liquid mixing space circulate, and a pressure adjusting member configured to provide a pressure to the liquids such that the liquids in the liquid mixing space flows into the circulation line and adjust the pressure.

The pressure adjusting member may include an impeller type pump.

The pressure adjusting member may include a pump configured to provide the pressure to the liquids, and a regulator configured to adjust an opening degree of the circulation line.

The circulation line may include a pipe extension that extends the length of a pipe within a limited distance.

The pipe extension may have a coil shape.

The length of the pipe extended by the pipe extension may be not less than 15 m and not more than 20 m.

The mixing member may further include a pressure sensor configured to measure a pressure in the circulation line, and a controller configured to control the pressure adjusting member to adjust a pressure in the circulation line based on a measurement value of the pressure sensor.

The controller may control the pressure adjusting member such that the pressure in the circulation line is not less than 220 Kpa and not more than 250 Kpa.

The first liquid may include a surfactant, and the second liquid may include pure water.

The inventive concept provides a substrate treating apparatus. The substrate treating apparatus includes a housing configured to provide a space for performing a substrate treating process in the interior thereof, a support unit configured to support the substrate within the housing and rotate the substrate, and a liquid supply unit configured to supply a cleaning liquid to a substrate positioned on the support unit, the cleaning liquid supply unit may include a mixing container having a liquid mixing space in the interior thereof, a first supply member configured to supply a first liquid into the liquid mixing space, a second supply member configured to supply a second liquid that is different from the first liquid into the liquid mixing space, and a mixing member configured to mix the first liquid and the second liquid supplied into the liquid mixing space, and the mixing member may include a circulation line, through which the liquids in the liquid mixing space circulate, and a pressure adjusting member configured to provide a pressure to the liquids such that the liquids in the liquid mixing space flows into the circulation line and adjust the pressure.

The pressure adjusting member may include an impeller type pump.

The pressure adjusting member may include a pump configured to provide the pressure to the liquids, and a regulator configured to adjust an opening degree of the circulation line.

The circulation line may include a pipe extension that extends the length of a pipe within a limited distance.

The pipe extension may have a coil shape.

The mixing member may include a pressure sensor configured to measure a pressure in the circulation line, and a controller configured to control the pressure adjusting member to adjust a pressure in the circulation line based on a measurement value of the pressure sensor.

The inventive concept provides a method for supplying a cleaning liquid to a substrate. The method including circulating a surfactant and pure water in a circulation line, measuring a pressure in the circulation line in real time when the surfactant and the pure water circulate, adjusting the pressure in the circulation line based on a value of the measured pressure to manufacture a cleaning liquid, and supplying the cleaning liquid to a substrate.

The circulation of the liquid in the circulation line may be performed by an impeller type pump, and the pressure in the circulation line may be adjusted by controlling an RPM of an impeller provided in the pump.

The pressure in the circulation line may be adjusted by adjusting an opening degree of the circulation line.

The length of the circulation line may be not less than 20 m and not more than 30 m.

The pressure in the circulation line may be adjusted to not less than 220 Kpa and not more than 250 Kpa.

### BRIEF DESCRIPTION OF THE FIGURES

The above and other objects and features of the inventive concept will become apparent by describing in detail exemplary embodiments thereof with reference to the accompanying drawings.

FIG. 1 is a view schematically illustrating a general cleaning liquid supply unit;

FIG. 2 is a plan view schematically illustrating an example of a substrate treating system that uses a cleaning liquid supplied according to an embodiment of the inventive concept;

FIG. 3 is a sectional view illustrating an example of a substrate treating apparatus provided in a process chamber of FIG. 2; and

FIG. 4 is a view schematically illustrating a part of a cleaning liquid supply unit of FIG. 3.

### DETAILED DESCRIPTION

Hereinafter, exemplary embodiments of the inventive concept will be described in more detail with reference to the accompanying drawings. The embodiments of the inventive concept may be modified in various forms, and the scope of the inventive concept should not be construed to be limited to the following embodiments. The embodiments of the inventive concept are provided to describe the inventive concept for those skilled in the art more completely. Accordingly, the shapes of the components of the drawings are exaggerated to emphasize clearer description thereof.

In the embodiments of the inventive concept, a substrate treating apparatus for performing a process of cleaning a substrate and a cleaning liquid supplying apparatus for manufacturing a cleaning liquid will be described. However, the inventive concept is not limited thereto, and may be applied to various types of apparatuses that manufacture and supply a cleaning liquid and clean a substrate by using the cleaning liquid.

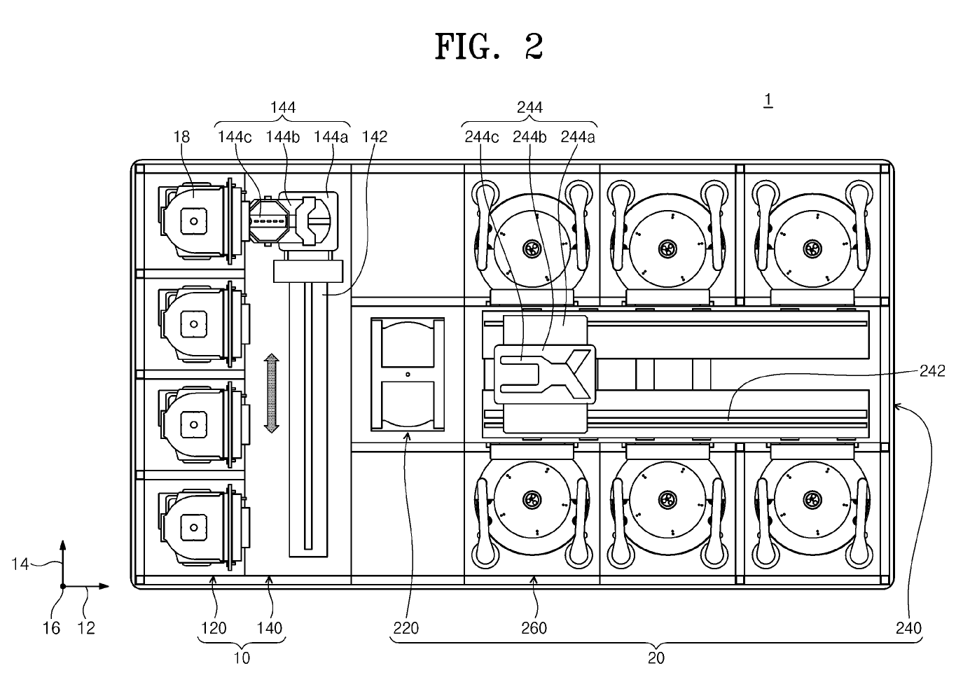

Hereinafter, exemplary embodiments of the inventive concept will be described with reference to FIGS. 2 to 4.

FIG. 2 is a plan view schematically illustrating an example of a substrate treating system 1 that uses a cleaning liquid manufactured according to an embodiment of the inventive concept.

Referring to FIG. 2, the substrate treating system 1 has an index module 10 and a process treating module 20, and the index module 10 has a plurality of load ports 120 and a feeding frame 140. The load ports 120, the feeding frame 140, and the process executing module 20 may be sequentially arranged in a row. Hereinafter, a direction in which the load port 120, the feeding frame 140, and the process treating module 20 will be referred to a first direction 12. A direction perpendicular to the first direction 12 when viewed from the top will be referred to as a second direction 14, and a direction normal to a plane including the first direction 12 and the second direction 14 will be referred to as a third direction 16.

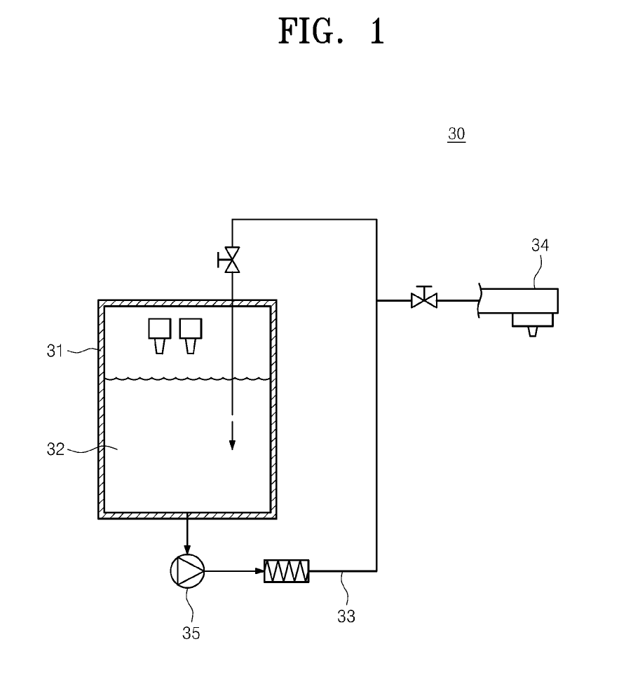

A carrier 130, in which a substrate W is received, is seated on the load port 120. A plurality of load ports 120 are provided, and are disposed along the second direction 14 in a row. FIG. 1 illustrates that four load ports 120 are provided. The number of the load ports 120 may be increased or decreased according to the process efficiency of the process executing module 20, a footprint condition, and the like. A plurality of slots (not illustrated) provided to support peripheries of substrates W are formed in the carrier 130. A plurality of slots are provided along the third direction 16, and the substrate W is situated in the carrier 130 such that the substrates W are stacked to be spaced apart from each other along the third direction 16. A front opening unified pod (FOUP) may be used as the carrier 130.

The process treating module 20 includes a buffer unit 220, a feeding chamber 240, and a plurality of process chambers 260. The feeding chamber 240 is disposed such that the lengthwise direction thereof is in parallel to the first direction 12. The process chambers 260 are disposed on opposite sides of the feeding chamber 240 along the second direction 14. The process chambers 260 situated on one side of the feeding chamber 240 and the process chambers 260 situated on an opposite side of the feeding chamber 240 are symmetrical to each other with respect to the feeding chamber 240. Some of the process chambers 260 are disposed along the lengthwise direction of the feeding chamber 240. Furthermore, some of the process chambers 260 are disposed to be stacked on each other. That is, the process chambers 260 having an array of A by B (A and B are natural numbers) may be disposed on one side of the feeding chamber 240. Here, A is the number of the process chambers 260 provided in a row along the first direction 12, and B is the number of the process chambers 260 provided in a row along the third direction 16. When four or six process chambers 260 are provided on one side of the feeding chamber 240, the process chambers 260 may be arranged in an array of 2 by 2 or 3 by 2. The number of the process chambers 260 may increase or decrease. Unlike the above-mentioned description, the process chambers 260 may be provided only on one side of the feeding chamber 240. Further, unlike the above-mentioned description, the process chambers 260 may be provided on one side or opposite sides of the feeding chamber 240 to form a single layer.

A buffer unit 220 is disposed between the feeding frame 140 and the feeding chamber 240. The buffer unit 220 provides a space in which the substrates W stay before being transported, between the feeding chamber 240 and the feeding frame 140. Slots (not illustrated) in which the substrates W are positioned are provided in the buffer unit 220, and a plurality of slots (not illustrated) are provided to be spaced apart from each other along the third direction 16. Faces of the buffer unit 220 that faces the feeding frame 140 and faces the feeding chamber 240 are opened.

The feeding frame 140 transports the substrates W between the carrier 130 seated on the load port 120 and the buffer unit 220. An index rail 142 and an index robot 144 are provided in the feeding frame 140. The index rail 142 is provided such that the lengthwise direction thereof is in parallel to the second direction 14. The index robot 144 is installed on the index rail 142, and is linearly moved in the second direction 14 along the index rail 142. The index robot 144 has a base 144a, a body 144b, and a plurality of index arms 144c. The base 144a is installed to be moved along the index rail 142. The body 144b is coupled to the base 144a. The body 144b is provided to be moved along the third direction 16 on the base 144a. The body 144b is provided to be rotated on the base 144a. The index arms 144c are coupled to the body 144b, and are provided to be moved forwards and rearwards with respect to the body 144b. A plurality of index arms 144c are provided to be driven individually. The index arms 144c are disposed to be stacked so as to be spaced apart from each other along the third direction 16. Some of the index arms 144c are used when the substrates W are transported to the carrier 130 in the process treating module 20, and some of the index arms 144c may be used when the substrates W are transported from the carrier 130 to the process treating module 20. This structure may prevent particles generated from the substrates W before the process treatment from being attached to the substrates W after the process treatment in the process of carrying the substrates W in and out by the index robot 144.

The feeding chamber 240 transports the substrates W between the buffer unit 220 and the process chambers 260, and between the process chambers 260. A guide rail 242 and a main robot 244 are provided in the feeding chamber 240. The guide rail 242 is disposed such that the lengthwise direction thereof is in parallel to the first direction 12. The main robot 244 is installed on the guide rail 242, and is linearly moved along the first direction 12 on the index rail 242. The main robot 244 has a base 244a, a body 244b, and a plurality of main arms 244c. The base 244a is installed to be moved along the guide rail 242. The body 244b is coupled to the base 244a. The body 244b is provided to be moved along the third direction 16 on the base 244a. The body 244b is provided to be rotated on the base 244a. The main arms 244c are coupled to the body 244b, and are provided to be moved forwards and rearwards with respect to the body 244b. A plurality of main arms 244c are provided to be driven individually. The main arms 244c are disposed to be stacked so as to be spaced apart from each other along the third direction 16. The main arms 244c used when the substrates W are transported from the buffer unit 220 to the process chambers 260 and the main arms 244 used when the substrates W are transported from the process chambers 260 to the buffer unit 220 may be different.

Substrate treating apparatuses 300 that perform cleaning processes on the substrates W are provided in the process chambers 260. The substrate treating apparatuses 300 provided in the process chambers 260 may have different structures according to the types of performed cleaning processes. Selectively, the substrate treating apparatuses 300 in the process chambers 260 may have the same structure. Selectively, the process chambers 260 may be classified into a plurality of groups such that the substrate treating apparatuses 300 provided in the process chambers 260 pertaining to the same group have the same structure and the substrate treating apparatuses 300 provided in the process chambers 260 pertaining to different groups has different structures. For example, when the process chambers 260 are classified into two groups, the first group of process chambers 260 may be provided on one side of the feeding chamber 240 and the second group of process chambers 260 may be provided on an opposite side of the feeding chamber 240. Selectively, the first group of process chambers 260 may be provided on the lower side of the feeding chamber 240 and the second group of process chambers 260 may be provided on the upper side of the feeding chamber 240, on opposite sides of the feeding chamber 240. The first group of process chambers 260 and the second group of process chambers 260 may be classified according to the kinds of the used chemicals or the types of cleaning methods.

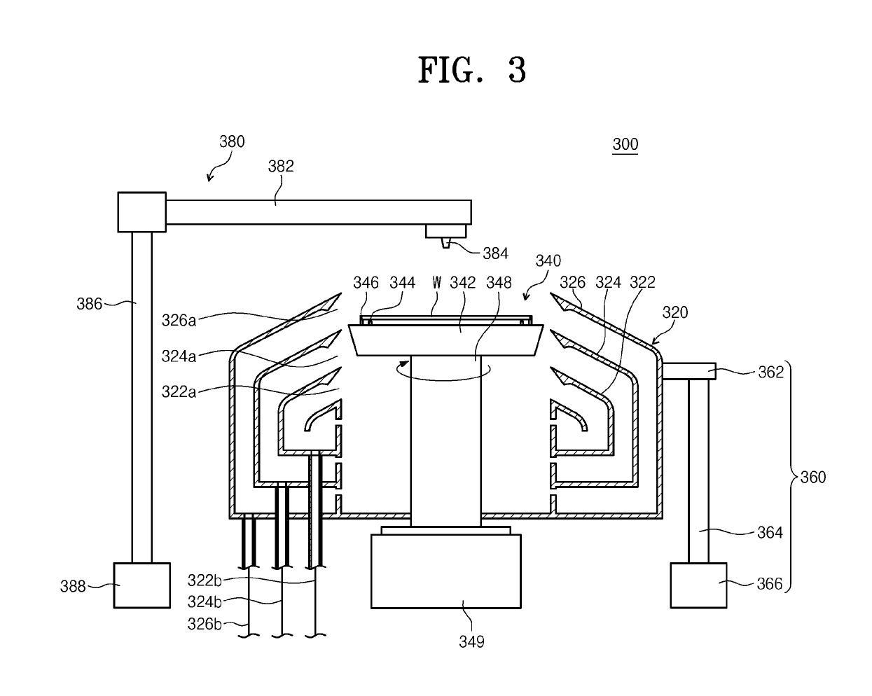

Hereinafter, an example of a substrate treating apparatus 300 that cleans a substrate W by using a treatment liquid will be described. FIG. 3 is a sectional view illustrating an example of the substrate treating apparatus 300 provided in the process chamber of FIG. 2. Referring to FIG. 3, the substrate treating apparatus 300 includes a housing 320, a support unit 340, and an cleaning liquid supply unit 380.

The housing 320 provides a space for performing a substrate treating process, and an upper side of the housing 320 is opened. The housing 320 has an inner recovery vessel 322, an intermediate recovery vessel 324, and an outer recovery vessel 326. The recovery vessels 322, 324, and 326 recover different treatment liquids used in the process. The inner recovery vessel 322 has an annular ring shape that surrounds the spin head 340, the intermediate recovery vessel 324 has an annular ring shape that surrounds the inner recovery vessel 322, and the outer recovery vessel has an annular ring shape that surrounds the intermediate recovery vessel 324. An inner space 322a of the inner recovery vessel 322, a space 324a between the inner recovery vessel 322 and the intermediate recovery vessel 324, and a space 326a between the intermediate recovery vessel 324 and the outer recovery vessel 326 function as inlets through which the treatment liquids are introduced into the inner recovery vessel 322, the intermediate recovery vessel 324, and the outer recovery vessel 326. Recovery lines 322b, 324b, and 326b extending from the recovery vessels 322, 324, and 326 perpendicularly in the downward direction of the bottom surfaces thereof are connected to the recovery vessels 322, 324, and 326, respectively. The recovery lines 322b, 324b, and 326b discharge the treatment liquids introduced through the recovery vessels 322, 324, 326, respectively. The discharged treatment liquids may be reused through an external treatment liquid recycling system (not illustrated).

The support unit is provided within the housing. A substrate W is positioned on the support unit. The support unit may be provided to the spin head 340. According to an embodiment, the spin head 340 is arranged within the housing 320. The spin head 340 supports and rotates the substrate W during the process. The spin head 340 has a body 342, a plurality of support pins 334, a plurality of chuck pins 346, and a support shaft 348. The body 342 has an upper surface having a substantially circular shape when viewed from the top. The support shaft 348 that may be rotated by a motor 349 is fixedly coupled to the bottom of the body 342. A plurality of support pins 334 are provided. The support pins 334 may be arranged to be spaced apart from each other at a periphery of the upper surface of the body 342 and protrude upwards from the body 342. The support pins 334 are arranged to have a generally annular ring shape through combination thereof. The support pins 334 support a periphery of a rear surface of the substrate W such that the substrate W is spaced apart from the upper surface of the body 342 by a predetermined distance. A plurality of chuck pins 346 are provided. The chuck pins 346 are disposed to be more distant from the center of the body 342 than the support pins 334. The chuck pins 346 are provided to protrude upwards from the body 342. The chuck pins 346 support a side of the substrate W such that the substrate W is not separated laterally from a proper place when the spin head 340 is rotated. The chuck pins 346 are provided to be linearly moved between a standby position and a support position along a radial direction of the body 342. The standby position is a position that is more distant from the center of the body 342 than the support position. When the substrate W is loaded on or unloaded from the spin head 340, the chuck pins 346 are located at the standby position, and when a process is performed on the substrate W, the chuck pins 346 are located at the support position. The chuck pins 346 are in contact with the side of the substrate W at the support position.

The elevation unit 360 linearly moves the housing 320 upwards and downwards. When the housing 320 moves upwards and downwards, a relative height of the housing 320 to the spin head 340 is changed. The elevation unit 360 has a bracket 362, a movable shaft 364, and a driver 366. The bracket 362 is fixedly installed on an outer wall of the housing 320, and the movable shaft 364 that moves upwards and downwards by the driver 366 is fixedly coupled to the bracket 362. The housing 320 is lowered such that, when the substrate W is positioned on the spin head 340 or is lifted from the spin head 340, the housing 320 is lowered such that the spin head 340 protrudes to the upper side of the housing 320. When the process is performed, the height of the housing 320 is adjusted such that the treatment liquid are introduced into the preset recovery vessel 360 according to the kind of the treatment liquid supplied to the substrate W. For example, a first treatment liquid, a second treatment liquid, and a third treatment liquid, which are different from each other, are supplied to the substrate, the substrate w is located at a height corresponding to the inner space 322a of the inner recovery vessel 322. Further, the substrate W may be located at a height corresponding to a space 324a between the inner recovery vessel 322 and the intermediate recovery vessel 324 and a space 326a between the intermediate recovery vessel 324 and the outer recovery vessel 3265 while the substrate W is treated by a second treatment liquid and a third treatment liquid. Unlike those described above, the elevation unit 360 may move the spin head 340, instead of the housing 320, upwards and downwards.

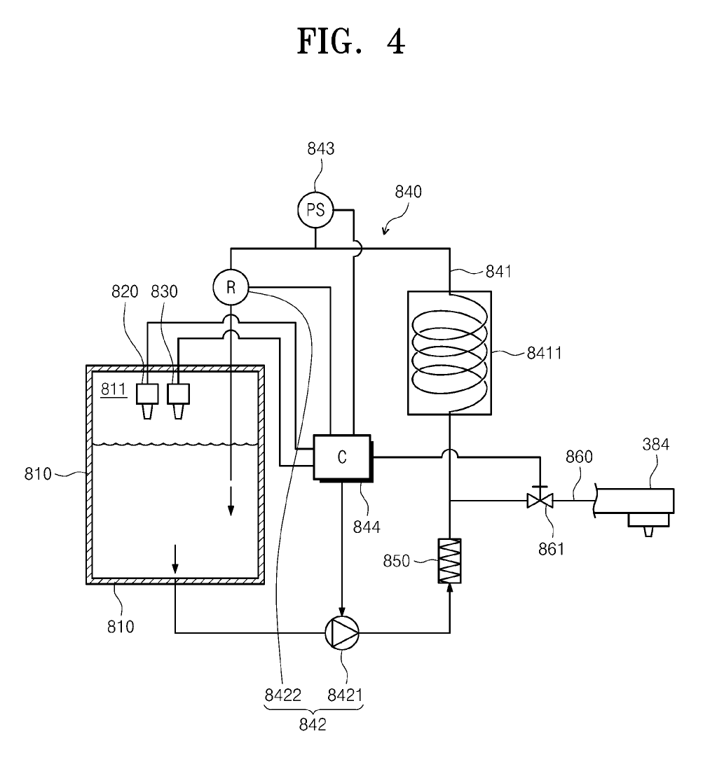

FIG. 4 is a view schematically illustrating a part of a cleaning liquid supply unit of FIG. 3. Referring to FIGS. 3 and 4, the cleaning liquid supply unit manufactures a cleaning liquid, and supplies the manufactured cleaning liquid to a substrate W positioned on the spin head 340 during a substrate treating process. The cleaning liquid supply unit 380 manufactures the cleaning liquid by mixing a first liquid and a second liquid. The first liquid and the second liquid are liquids of different kinds. According to an embodiment, the first liquid is provided as a surfactant chemical including a surfactant and the second liquid is provided as pure water. For example, a chemical of ‘SAP 1.0’ of ‘Dong-Woo Fine Chemistry Inc.’ is provided as the surfactant chemical. Unlike this, the first liquid and the second liquid may be provided as various kinds of chemical liquids which can be used as a cleaning liquid in which particles are mixed with each other.

The cleaning liquid supply unit 380 includes a nozzle support 382, a nozzle 384, a support shaft 386, a driver 388, a mixing container 810, a first supply member 820, a second supply member 830, and a mixing member 840. The substrate treating apparatus 300 may further include a supply unit that supplies a treatment liquid that is the same as or different from that of the cleaning liquid supply unit 380 to a substrate W.

The lengthwise direction of the support shaft 386 is provided along the third direction 16, and the driver 388 is coupled to a lower end of the support shaft 386. The driver 388 rotates and elevates the support shaft 386. The nozzle support 382 is coupled to an end of the support shaft 386, which is opposite to an end of the support shaft 386 coupled to the driver 388, perpendicularly to the support 386.

The nozzle 384 is installed on a bottom surface of an end of the nozzle support 382. The nozzle 384 is moved to a process location and a standby location by the driver 388. The process location is a location at which the nozzle 384 is arranged at a vertical upper portion of the housing 320, and the standby location is a location that deviates from the vertical upper portion of the housing 320. The nozzle 384 discharges the cleaning liquid supplied onto the substrate W positioned on the spin head 340.

The mixing container 410 has a liquid mixing space 811, in which the liquid supplied into the mixing container 410 are mixed. A wall of the mixing container 410 may be insulated in order that heat exchange of the housing 410 with the outside may be minimized so that the temperature of the liquid supplied into the liquid mixing space 811 may be easily adjusted. The mixing container 410 may be provided with a temperature sensor that measures the temperature of the liquids in the liquid mixing space 811. The temperature of the liquids measured by the temperature sensor is delivered to the controller 844.

The first supply member 420 supplies a first liquid into the liquid mixing space 811. The second supply member 830 supplies a second liquid into the liquid mixing space 811.

The mixing member 840 mixes the first liquid and the second liquid supplied into the liquid mixing space 811. According to an embodiment, the mixing member 840 includes a circulation line 841, a pressure adjusting member 842, a pressure sensor 843, and a controller 844.

The liquid in the liquid mixing space 811 circulates in the circulation line 841. The first liquid and the second liquid supplied to the liquid mixing space 811 are mixed with each other while circulating through the circulation line 841, and generated the cleaning liquid in which the particles are formed.According to an embodiment, opposite ends of the circulation line 841 are connected to the liquid mixing space, and the liquids supplied into the liquid mixing space flows in the supply line 441. The first liquid and the second liquid supplied into the liquid mixing space 811 are mixed as they pass through the circulation line 841 and circulate into the liquid mixing space 811 again. The circulation line 841 may be insulated such that heat exchange between the interior and exterior of the circulation line 441 may be minimized. According to an embodiment, the supply line 460 connected to the nozzle 384 is connected to the circulation line 841. An opening/closing valve 461 is provided in the circulation line 841. The controller 844 that will be described below opens the opening/closing valve 461 if the cleaning liquid is completely manufactured, and supplies the cleaning liquid to the substrate W through the nozzle 384.

The pressure adjusting member 842 provides a pressure to the liquid in the circulation line such that the liquid in the liquid mixing space 811 flows into the circulation line 841. The pressure adjusting member 842 adjusts the pressure applied to the liquid in the circulation line 841. According to an embodiment, the pressure adjusting member 842 includes a pump 8421 and a regulator 8422.

The pump 8421 applies a pressure such that the liquid in the circulation line 841 circulates through the circulation line 841. According to an embodiment, the pump 8421 is an impeller type pump. The impeller type pump generally may apply a high pressure and maintain the pressure constantly as compared with a bellows type pump for providing a pressure that circulates the liquid in the circulation line 841.

The regulator 8422 adjusts an opening degree of the circulation line 841. The regulator 8422 may not be provided when the pump 8421 is an impeller type pump. Unlike this, when the regulator 8422 is provided, the pump 8421 may be a pump other than an impeller type pump.

The pressure sensor 843 measures a pressure in the circulation line 841 in real time. A measurement value of a pressure in the circulation line 841 measured by the pressure sensor 843 is delivered to the controller 844.

The controller 844 controls the pressure adjusting member 842 to adjust a pressure in the circulation line 841 based on a real-time measurement value of the pressure in the circulation line 841 measured by the pressure sensor while the first liquid and the second liquid circulate in the circulation line 841. The controller 844 controls the pressure adjusting member 842 to maintain the pressure in the circulation line 841 at a pressure, by which the particles in the cleaning liquid is provided to have a suitable size, while the first liquid and the second liquid circulate in the circulation line 841. According to an embodiment, the first liquid is a chemical of ‘SAP 1.0’ of ‘Dongwoo Fine Chem Inc.’ and the second liquid is pure water, and the controller 844 controls the pressure adjusting member 842 such that the pressure in the circulation line 841 is not less than 220 Kpa and not more than 250 Kpa. In this case, the diameters of the particles generated in the cleaning liquid may be about 22 μm. According to an embodiment, the controller 844 adjusts the pressure in the circulation line 841 by adjusting the RPM of the impeller of the impeller type pump and/or the opening degree of the regulator.

The pipe extension 8411 extends the length of the pipe of the circulation line 841 within a limited distance. According to an embodiment, the pipe extension 8411 has a coil shape. For example, when the length of the pipe of the circulation line 841 extended by the pipe extension 8411 is not less than 15 m and not more than 20 m, the total length of the circulation line 841 may be not less than 20 m and not more than 30 m. The particles in the cleaning liquid which are produced by circulating the circulating line 841 can be generated as large as the length of the circulating line 841 in which a constant pressure can be maintained. By providing the pipe extension 8411 that may extend the length of the pipe of the circulation line 841 within a limited distance, the size of the particles may be increased by extending the length of the circulation line 841 without increasing the footprint of the apparatus excessively. Generally, the larger the particles in the cleaning liquid, the more the cleaning effect of the substrate is increased.

As mentioned above, the apparatus according to an embodiment of the inventive concept may increase the sizes of the particles in the cleaning liquid without increasing the footprint of the apparatus excessively by adjusting the pressure in the circulation line and increasing the length of the circulation line when the first liquid and the second liquid are mixed to manufacture a cleaning liquid.

According to the apparatus and the method an embodiment of the inventive concept, the pressure in the circulation line may be adjusted.

Further, according to the apparatus and the method according to an embodiment of the inventive concept, the length of the circulation line may be extended within a limited distance.

According to the apparatus and the method the embodiments of the inventive concept, the sizes of the particles in the cleaning liquid may be increased.

What is claimed is:

1. A cleaning liquid supply unit for supplying a cleaning liquid that cleans a substrate, the cleaning liquid supply unit comprising:
a mixing container having a liquid mixing space in the interior thereof;
a first supply member configured to supply a first liquid into the liquid mixing space;
a second supply member configured to supply a second liquid that is different from the first liquid into the liquid mixing space; and
a mixing member configured to mix the first liquid and the second liquid supplied into the liquid mixing space,
wherein the mixing member includes:
a circulation line, through which the liquids in the liquid mixing space circulate; and
a pressure adjusting member configured to provide a pressure to the liquids such that the liquids in the liquid mixing space flows into the circulation line and adjust the pressure.

2. The cleaning liquid supply unit of claim 1, wherein the pressure adjusting member includes an impeller type pump.

3. The cleaning liquid supply unit of claim 1, wherein the pressure adjusting member includes:
a pump configured to provide the pressure to the liquids; and
a regulator configured to adjust an opening degree of the circulation line.

4. The cleaning liquid supply unit of claim 1, wherein the circulation line includes a pipe extension that extends the length of a pipe within a limited distance.

5. The cleaning liquid supply unit of claim 4, wherein the pipe extension has a coil shape.

6. The cleaning liquid supply unit of claim 5, wherein the length of the pipe extended by the pipe extension is not less than 15 m and not more than 20 m.

7. The cleaning liquid supply unit of claim 1, wherein the mixing member further includes:
a pressure sensor configured to measure a pressure in the circulation line; and
a controller configured to control the pressure adjusting member to adjust a pressure in the circulation line based on a measurement value of the pressure sensor.

8. The cleaning liquid supply unit of claim 6, wherein the controller controls the pressure adjusting member such that the pressure in the circulation line is not less than 220 Kpa and not more than 250 Kpa.

9. The cleaning liquid supply unit of claim 1, wherein the first liquid includes a surfactant, and the second liquid includes pure water.

10. A substrate treating apparatus comprising:
a housing configured to provide a space for performing a substrate treating process in the interior thereof;
a support unit configured to support the substrate within the housing and rotate the substrate; and
a liquid supply unit configured to supply a cleaning liquid to a substrate positioned on the support unit,
wherein the cleaning liquid supply unit includes:
a mixing container having a liquid mixing space in the interior thereof;
a first supply member configured to supply a first liquid into the liquid mixing space;
a second supply member configured to supply a second liquid that is different from the first liquid into the liquid mixing space; and
a mixing member configured to mix the first liquid and the second liquid supplied into the liquid mixing space, and
wherein the mixing member includes:
a circulation line, through which the liquids in the liquid mixing space circulate; and
a pressure adjusting member configured to provide a pressure to the liquids such that the liquids in the liquid mixing space flows into the circulation line and adjust the pressure.

11. The substrate treating apparatus of claim 10, wherein the pressure adjusting member includes an impeller type pump.

12. The substrate treating apparatus of claim 10, wherein the pressure adjusting member includes:
a pump configured to provide the pressure to the liquids; and
a regulator configured to adjust an opening degree of the circulation line.

13. The substrate treating apparatus of claim 10, wherein the circulation line includes a pipe extension that extends the length of a pipe within a limited distance.

14. The substrate treating apparatus of claim 13, wherein the pipe extension has a coil shape.

15. The substrate treating apparatus of claim 13, wherein the mixing member includes:
a pressure sensor configured to measure a pressure in the circulation line; and
a controller configured to control the pressure adjusting member to adjust a pressure in the circulation line based on a measurement value of the pressure sensor.

16. A method for supplying a cleaning liquid to a substrate, the method comprising:
circulating a surfactant and pure water in a circulation line;
measuring a pressure in the circulation line in real time when the surfactant and the pure water circulate;
adjusting the pressure in the circulation line based on a value of the measured pressure to manufacture a cleaning liquid; and
supplying the cleaning liquid to a substrate.

17. The cleaning liquid supply method of claim 16, wherein the circulation of the liquid in the circulation line is performed by an impeller type pump and the pressure in the circulation line is adjusted by controlling an RPM of an impeller provided in the pump.

18. The cleaning liquid supply method of claim 16, wherein the pressure in the circulation line is adjusted by adjusting an opening degree of the circulation line.

19. The cleaning liquid supply method of claim 16, wherein the length of the circulation line is not less than 20 m and not more than 30 m.

20. The cleaning liquid supply method of claim 16, wherein the pressure in the circulation line is adjusted to not less than 220 Kpa and not more than 250 Kpa.
